(19) United States
(12) Patent Application Publication
(10) Pub. No.: US 2008/0057611 A1
(43) Pub. Date: Mar. 6, 2008

(54) METHOD OF MANUFACTURING A THIN-FILM THERMO-ELECTRIC GENERATOR

(75) Inventors: Matthias Stordeur, Halle (DE); Bernd Engers, Halle (DE); Jens Schultz, Halle (DE)

Correspondence Address: DUANE MORRIS, LLP;IP DEPARTMENT, 30 SOUTH 17TH STREET, PHILADELPHIA, PA, 19103-4196, US

(73) Assignee: ANGARIS GMBH, Halle (DE)

(21) Appl. No.: 11/837,298

(22) Filed: Aug. 10, 2007

(30) Foreign Application Priority Data
Aug. 30, 2006 (DE) 102006040576.5-33

(51) Int. Cl. H01L 21/00

(52) U.S. Cl. 438/54; 257/E21.002

(57) ABSTRACT

A method of manufacturing a thin-film thermoelectric generator comprises the steps of: coating of a carrier film with a first semiconductor of a first conductor type, structuring of the first semiconductor, coating of the carrier film with a second semiconductor of a second conductor type and structuring of the second semiconductor. The carrier film is provided for the coating and structuring operations as a film roll.

The invention relates to a method of manufacturing a thin-film thermo-electric generator.

A thermoelectric generator is a device which has at least one thermocouple.

The thermocouple comprises two legs of different, electrically conductive materials, which at one of their ends are in electrical contact with one another, whilst their other ends are electrically open or may be connected to an electrical circuit. In the event of a temperature difference between the ends of the legs, a thermoelectric voltage is generated between the open ends of the legs (Seebeck effect). When the circuit is closed, an electric current flows.

Methods for the manufacture of a thin-film thermo-electric generator are disclosed by DE 103 33 084 A1 and US 2005/0252543 A1, for example. In the methods described there, thermocouples are made in-plane, i.e. in a plane, from tellurium compound semiconductors by means of sputtering, photolithography and wet-chemical etching on a film. The size of the film corresponds to the common size of silicon wafers, for example 3 to 6 inches. An alternative method is described by H. Bottner et al. in “Thermoelectrics Handbook Macro to Nano”, CRC Press Taylor & Francis Boca Raton, New York, London, 46-1 (2005). In this method thin-film thermo-electric generators and thin-film Peltier coolers are manufactured by sputtering from tellurium compound semiconductors. In this method the structuring is achieved by dry etching. The substrates are formed by Si/SiO₂ wafers, the thermocouples having legs, which run over the extent of the wafer film thickness and hence perpendicular to the substrate plane. A disadvantage of this method lies in the complicated handling of the film pieces or wafers and the resulting low productivity.

DE 30 14 851 A1 discloses a device for depositing thin films under vacuum. The use of this device is restricted to processes running under a uniform (low) pressure and in a uniform atmosphere. Such processes serve, for example, for the manufacture of coated plastic films for motor vehicle glazing and cannot be used in the manufacture of thin-film thermo-electric generators owing to the varying pressures at different stages in the process.

### SUMMARY OF THE INVENTION

A method of manufacturing a thin-film thermoelectric generator, comprising the steps of: coating of a carrier film with a first semiconductor of a first conductor type, structuring of the first semiconductor, coating of the carrier film with a second semiconductor of a second conductor type, structuring of the second semiconductor, and providing the carrier film for the coating and structuring steps as a film roll.

### BRIEF DESCRIPTION OF THE DRAWINGS

An exemplary method will be explained in more detail below with reference to the drawings, in which:

FIG. 1 shows a schematic representation of a device for the preheating of a carrier film in an exemplary method according to the invention,

FIG. 2 shows a schematic representation of a device for inverse sputter-etching for cleaning the carrier film in an exemplary method according to the invention,

FIG. 3 shows a schematic representation of a system for coating the carrier film for performing a coating operation in an exemplary method according to the invention,

FIG. 4 shows a schematic representation of a coated carrier film after structuring of the first semiconductor,

FIG. 5 shows a schematic representation of a coated carrier film after structuring of the second semiconductor,

FIG. 6 shows a schematic representation of a device for metal coating for bonding of the carrier film in an exemplary method according to the invention,

FIG. 7 shows a schematic representation of a completely coated, patterned and bonded carrier film, which comprises a thin-film thermo-electric generator.

Some embodiments provide an improved method of manufacturing a thin-film thermo-electric generator, which affords an increased productivity in the manufacture of thin-film thermo-electric generators of in-plane configuration.

Some embodiments allow a continuous coating and a continuous structuring. It is therefore not necessary, in the exemplary method, to handle the carrier films of wafer size. Instead, it is possible to perform the method continuously, so that interruptions and set-up times are minimized.

Provision of the carrier film for the coating and structuring operations in the form of a film roll furthermore opens up the possibility of manufacturing extensive thin-film thermo-electric generators.

A further advantage is that with the exemplary method multiple, dissimilar processing operations (coating and structuring) can each be efficiently performed in sequence with specific devices and processing speeds.

The term “conductor type of a semiconductor” relates to the characteristic of the semiconductor which makes it either a p-type semiconductor or an n-type semiconductor. The semiconductors are preferably tellurium compound semiconductors of the n-type or the p-type, which have compositions like those described in DE 103 33 084 A1.

A “carrier film” is in particular taken to mean a plastic web having a thickness of less than 0.5 mm. The thickness of the carrier film is preferably between 7 μm and 100 μm. The width of the carrier film is preferably less than one metre, in particular 80 cm or less, which facilitates the handling of the carrier film. In order to achieve the highest possible productivity, the width of the carrier film is preferably in excess of 50 cm. The carrier film is preferably in web form and the length of the carrier film is in particular at least ten times the width of the carrier film, being 5 to 8 m, for example. To facilitate processing, the carrier film is preferably flatly extensible and of single-layer construction, and in particular has an untextured, macroscopically smooth surface.

The carrier film is preferably comprised of plastics, and in particular of polyimide, such as Kapton®, for example. The carrier film moreover preferably has a low thermal conductivity, in particular of less than 0.6 W/mK. The coefficient of thermal expansion is also preferably selected so that no thermal stresses occur between the deposition film coating and the carrier film, which could lead to detachment of the film coating.

In the context of this description, the term “provision of the carrier film” is taken to mean that the carrier film is fed from the film roll directly to the respective coating or structuring, that is to say, in particular, the carrier film is not divided up prior to the coating and structuring operations, but is delivered as a whole directly to the respective coating or structuring operation.

It is possible, although not essential, for the carrier film to be provided in the form of a spiral film roll. The term “film roll” in particular includes any compact arrangement of the carrier film in wound or laid form, for example in transportable packages. For example, the carrier film may be provided folded in layers in open containers.

In a preferred method the carrier film in each of the coating operations runs off one roll holder onto another roll holder. This advantageously affords scope for a charge process or a batch process.

In an especially preferred method the carrier film runs from one roll holder onto a succeeding roll holder at least in the first structuring operation. It is especially preferred that in all coating operations and in all structuring operations the carrier film should in each case run from one roll holder onto a succeeding roll holder, which then serves to provide the carrier film for the succeeding operation.

If the method is performed in spatially separated devices, for example, the carrier film is first coated with a first semiconductor of a first conductor type in one coating device and then runs onto a succeeding roll holder. On this roll holder the carrier film is then transported to a structuring device and is provided for a structuring operation. The structuring is then performed, the carrier film running onto a further roll holder.

On this roll holder the carrier film is then provided for coating with a second semiconductor of a second conductor type and the coating is performed. After coating, the carrier film again runs onto a roll holder and on this roll holder is provided for the structuring of the second semiconductor. The advantage of this is that one coating device is sufficient for both coating operations and one structuring device is sufficient for both structuring operations.

In a preferred method different pressures are provided for each of the coating and structuring operations. The processing operations, in particular the coating and structuring operations can then advantageously be performed at an appropriate pressure, which improves the quality of the thin-film thermo-electric generators.

In a preferred method the coating operations take place under a vacuum and the structuring operations at atmospheric pressure. In an especially preferred method the coating operations are performed in a coating device and the carrier film is introduced into or extracted (discharged) from the coating device for the coating. Here, the coating operations may but need not necessarily be performed in one and the same coating device.

In an especially preferred method a sealed roll magazine is used to introduce/extract the carrier film. A roll magazine is here taken to mean a roll holder with a sealable housing. A standardized roll magazine is preferably used, that is to say the method according to the invention is performed using only one type of roll magazine.

In a preferred variant of the method the carrier film is introduced into and extracted from the respective coating device by introducing or extracting the roll holder in its entirety. For this purpose the roll holder is inserted into a lock device, which is part of the respective coating device. The lock device is then brought to the pressure prevailing in the coating operation. It is then opened so that the carrier film can be moved into and through the coating device and coated.

In a preferred method at least one of the coating operations or structuring operations is performed continuously. A “continuous performance” is here, in particular, taken to mean that the carrier film moves at a constant speed relative to the device performing the processing operation. In an alternative method at least one of the coating operations or structuring operations is performed “quasi-continuously.” This is taken to mean that the carrier film is drawn off from the film roll at a substantially constant speed, but is temporarily arrested by a retarding device so that it is stationary relative to a photomask used in the structuring, for example (see below).

In a preferred method different processing speeds are used for the coating and structuring operations. In this case the processing speeds for the coating and structuring operations may differ from one another, so that the coating operations and the structuring operations can be performed at different rates. This has the advantage that each of the coating and structuring operations can be performed at the respective optimum speed. A further advantage is that in the event of operating malfunctions the other coating and structuring operations are not adversely affected. This improves the reliability of the process.

In an especially preferred method the carrier film is cleaned, in particular by inverse sputter-etching, prior to coating. The inverse sputter-etching is preferably performed in a vacuum and by means of argon ions, a pressure of 0.2 to 0.3 Pa prevailing and the net area power density preferably being in the order of 0.4 to 0.9 W/cm².

In a preferred method the carrier film is provided on the roll holder for a succeeding structuring operation, the structuring of the semiconductors being performed by photolithography and wet chemical means. Details of the structuring method are set forth in DE 103 33 084 A1. Immersion in a dip coater or application by a spray process is especially suitable for the application of photoresist to the carrier film for photolithographic structuring. A pattern transfer of a photomask can be performed by means of the known “step and repeat” method.

In a preferred method the carrier film is tempered prior to coating, in particular at 250° C. to 350° C. Especially good tempering results can be achieved at a tempering temperature of 290° C. to 310° C., maintained for 1 to 3 hours.

In an especially preferred method the carrier film, for coating, is first coated with a film to a thickness of between 10 nm and 100 nm in a first coating operation, this coating being performed at less than 100° C., in particular at room temperature (23° C.). In a subsequent, second part of the operation, the carrier film is then coated at a temperature of 200° C. to 300° C. with a film having a film thickness of 0.5 μm to 100 μm. This has proved to afford a particularly high bond strength of the film coating on the carrier film.

The coating is preferably undertaken by high-rate magnetron sputtering, in particular dc high-rate magnetron sputtering.

In a preferred method, after the structuring of the second semiconductor, bonding and thereafter lacquer coating are undertaken. The lacquer coating is preferably followed by tempering under a protective gas atmosphere. A nitrogen atmosphere has proved particularly suitable, tempering being performed for a period of between 1 to 3 hours, in particular 2 hours, at a temperature of between 250° C. and 350° C. An increase in the electrical conductivity is thus advantageously achieved, without any significant reduction in the Seebeck coefficient.

The exemplary embodiment will be described below with particular reference to features of the preparation and transport of the carrier film. Further details of the process control, such as the composition of the first and second semiconductor, for example, the sequence of the coating and structuring operations, the etching process, the bonding operation and the further processing of the bonded carrier film, in particular the formation of stacks of thermoelectric components, are disclosed by DE 103 33 084 A1, which is hereby incorporated by reference in its entirety into the present description.

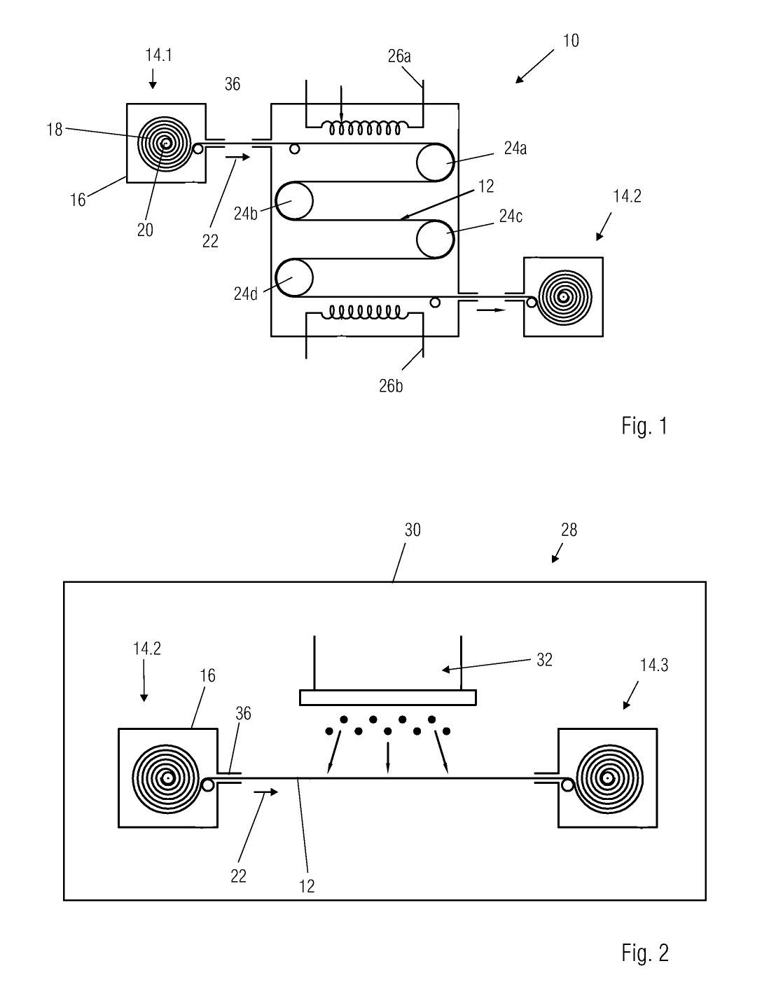

FIG. 1 shows a pre-treatment device 10 for the preheating of a carrier film 12. The pre-treatment device 10 in a chamber comprises four idling rollers 24a to 24d, for example, and two electrical heating resistors 26a, 26b, for example, which interact as follows.

The carrier film 12 is moved from the roll magazine 14.1, which has a housing 16 in which the carrier film 12 is disposed in the form of a film roll 18 on a roll holder 20, towards the pre-treatment device 10 (see arrow 22). The carrier film 12 enters the pre-treatment device 10 through an inlet opening and is led on a meandering course over the idling rollers 24a to 24d inside the pre-treatment device 10. The carrier film 12, which is composed of polyimide, is heated by the electrical heating resistors 26a, 26b on the front and rear sides to 300° C. and kept at this temperature for approximately 2 hours inside the pre-treatment device 10. This preheating, which constitutes a tempering, serves to prevent a shrinkage of the carrier film 12 in subsequent processing operations.

The carrier film 12 leaves the pre-treatment device 10 and after cooling to a temperature, selected so that no sticking of the carrier film 12 occurs, is taken up in a further roll magazine 14.2, which is drawn in on the right in FIG. 1. Where necessary, this process is repeated until the carrier film 12 has predefined characteristics, for example until it no longer exhibits any further shrinkage.

In an alternative method the carrier film 12 is stored for approximately 2 hours at a temperature of 300° C. without moving. The storage is here performed so that the surfaces of the carrier film 12 do not touch one another, so as to avoid any sticking. This storage, like the tempering process shown in FIG. 1, takes place in a filtered air atmosphere at ambient temperature.

FIG. 2 shows a sputter etching unit 28, which comprises a vacuum chamber 30 and an argon ion source 32. Prior to cleaning of the carrier film 12, the roll magazine 14.2 is first evacuated, so that the same pressure prevails in the roll magazine 14.2 as in the vacuum chamber 30, for example 0.2 to 0.3 Pa. The carrier film 12 is then provided for the cleaning operation by drawing it out of the housing 16 of the roll magazine 14.2 and feeding it past the argon ion source 32 in the direction of the arrow 22.

The argon ion source 32 serves to bombard the carrier film 12, which is fed past the argon ion source 32 at a constant speed, with argon ions at an RF net area power density of 0.4 to 0.9 W/cm². The surface of the carrier film 12 thereby experiences a fine cleaning and at the same time a roughening in the nanometre range. The latter helps to improve the bond strength for a coating applied in further processing. The bond strength thus attainable constitutes an important advantage by reducing the risk of subsequently applied semiconductors becoming detached from the carrier film, even under the mechanical stresses that can occur, for example, in a mechanical separation of the carrier film. Such a separation may be provided for in a method designed to provide for a final micro-assembly of the thin-film thermo-electric generators.

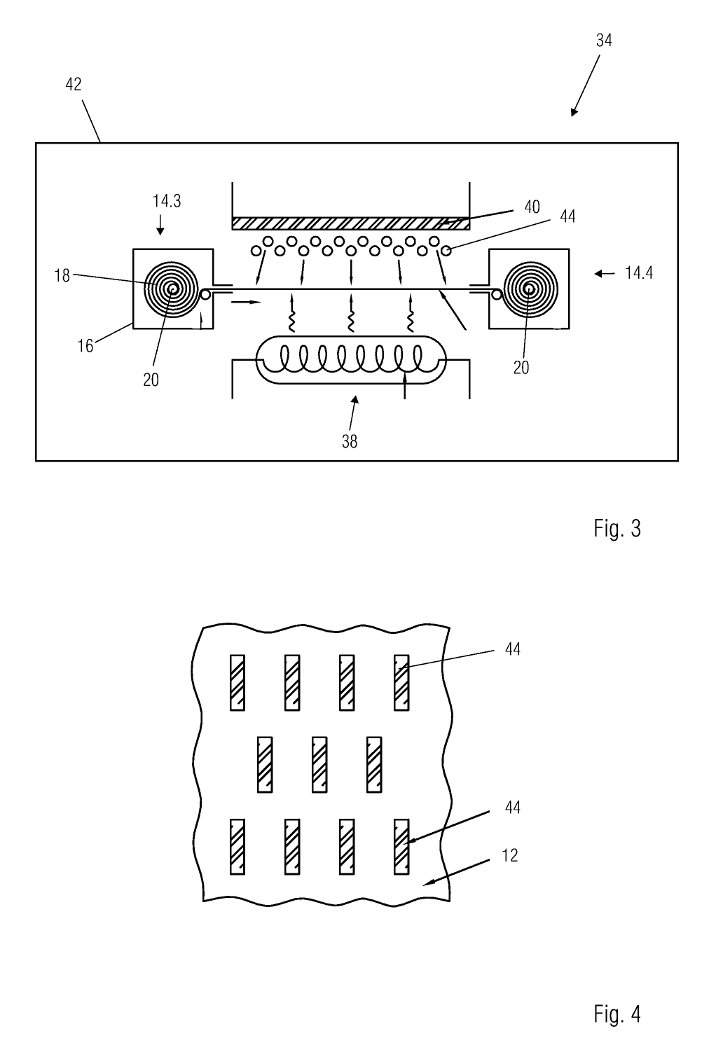

After cleaning, the carrier film 12 is taken up in a further roll magazine 14.3 drawn in on the right in FIG. 2. The roll magazine 14.3 is then sealed and provided for the succeeding coating operation described with reference to FIG. 3.

FIG. 3 shows a coating device 34 for performing a dc high-rate magnetron sputtering, which comprises a radiant heating 38, a target 40 and a vacuum chamber 42. The roll magazine 14.3 is introduced into the vacuum chamber 42. The carrier film 12 then leaves the roll magazine 14.3 and in the unheated state is first coated with a film of a first p-type semiconductor 44 by dc high-rate magnetron sputtering (cold sputtering). The film thickness is 10 nm to 100 nm. The target 40 here serves as sputtering source.

The carrier film 12 then runs into an area of the coating device 34 in which it is heated by the radiant heating 38 on the rear side to a temperature of approximately 250° C. A film of the same p-type semiconductor 44 as in the cold sputtering is then deposited by dc high-rate magnetron sputtering. The film thickness is between 0.5 μm and 100 μm. The sputtering onto the heated carrier film 12 is referred to as hot sputtering.

Both the hot sputtering and the cold sputtering run continuously and in series by feeding the carrier film 12 past the target 40 at a constant speed. Throughout the cold and hot sputtering, a pressure of 0.2 to 0.5 Pa prevails in the vacuum chamber 42. The area power density in the cold sputtering is between 0.4 and 0.8 W/cm², and in the hot sputtering between 0.8 and 1.6 W/cm².

In the material sputtering area the target 40 comprises a p-tellurium compound semiconductor, as is described, for example, in DE 103 33 084 A1.

After coating with the p-type semiconductor 44, the carrier film 12 runs onto a succeeding roll holder 20 in the roll magazine 14.4 drawn in on the right in FIG. 3. The roll holder 20 has a radius of curvature of at least 3 cm. This ensures that the coating is not damaged by rolling up.

The roll magazine 14.4 is then sealed and extracted from the vacuum chamber 42 and provided for a succeeding structuring operation. For this purpose the roll magazine 14.4 is first brought to ambient pressure, for example by feeding air or a protective gas into the lock and delivering to a structuring device (not shown here).

An exemplary method for the subsequent structuring is described in DE 103 33 084 A1. In the course of structuring of the first semiconductor 44, a photoresist is applied to the carrier film 12. Immersion in a specially dimensioned dip coater or an application of the photoresist by a spraying process is suitable for application of the photoresist. In order to illuminate the photoresist, a photomask is used to transfer a corresponding pattern onto the photoresist by means of an optical-projective “step and repeat” process known in the art. This method is repeated sequentially. When illuminating by means of the photomask, the carrier film 12 is stationary relative to the photomask.

A subsequent chemical erosion for structuring of the first semiconductor 44 is performed by extensive spray etching. Alternatively, the chemical erosion is achieved by wet etching. The p-type first tellurium compound semiconductor is etched with an aqueous solution of tetrafluoro-boric acid (HBF₄), tartaric acid and hydrogen peroxide (H₂O₂).

FIG. 4 shows a schematic representation of the carrier film 12 with the patterned first semiconductor 44 arranged thereon.

After structuring, the carrier film 12 again runs onto the roll holder 20 in the roll magazine. The roll magazine is then sealed and is again introduced into the coating device 34 shown in FIG. 3.

In a succeeding coating operation the carrier film is coated with a second semiconductor 46 of a second conductor type, that is an n-type tellurium compound semiconductor. The process here is as described above. Details of the composition of the second semiconductor 46 are given in DE 103 33 084 A1.

The second semiconductor is then structured in the manner described above. This structuring of the second semiconductor 46 is done selectively, so that the first semiconductor 44 is unaffected by the structuring of the second semiconductor 46. An aqueous solution of perchloric acid (HClO₄) and hydrogen peroxide is used as etching solution. Details of the etching process for the two semiconductors may be as given in DE 103 33 084 A1.

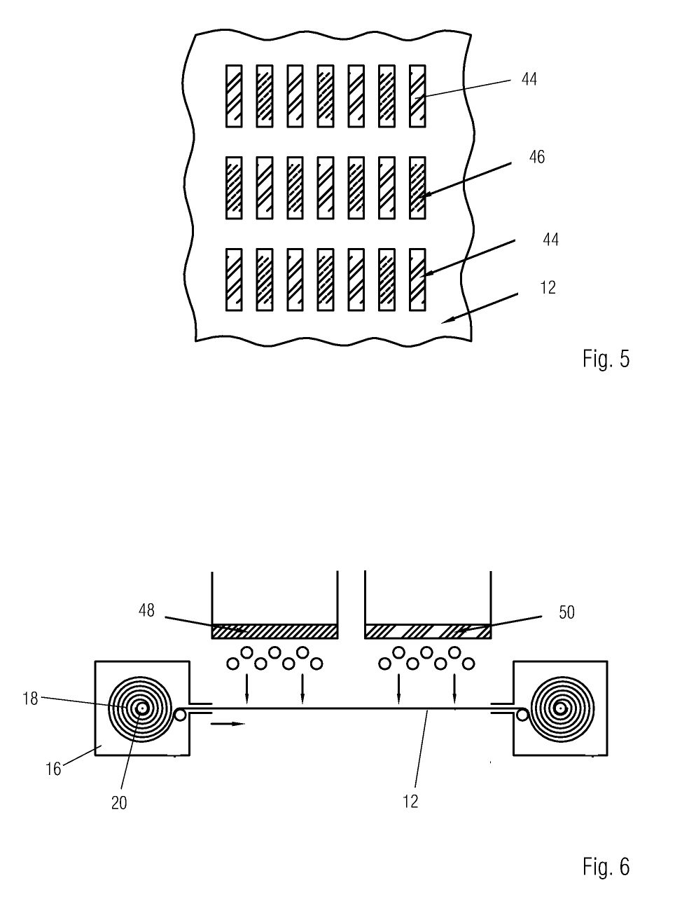

FIG. 5 schematically represents the carrier film 12 with the structured first semiconductor 44 and the structured second semiconductor 46.

After structuring of the second semiconductor 46, the carrier film 12 again runs onto the roll holder of the roll magazine. The carrier film 12 is again taken from the roll magazine and is provided for a bonding operation described below.

For the purpose of bonding, a lift-off mask, which by means of photolithography is formed so that it has openings at the points where the bonding is to be applied in a subsequent processing operation (see below), is first applied to the carrier film 12.

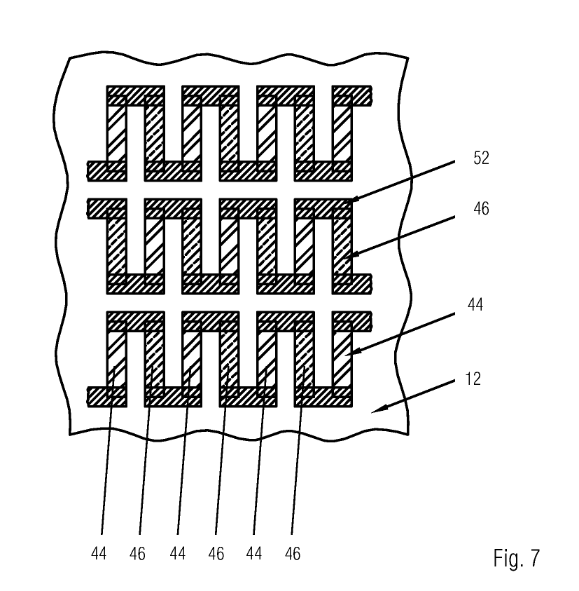

For the purpose of bonding, the unheated carrier film 12, as represented schematically in FIG. 6, then runs out of the roll magazine 14.5 and past a nickel target 46 followed by a gold target 50, so that first a nickel film having a thickness of 2 μm to 5 μm and then a gold film having a thickness of approximately 150 nm are applied by sputtering to those points on the carrier film 12 that are not covered by the lift-off mask. The nickel film constitutes an interconnection 52 for the coatings with the first semiconductor 44 and the second semiconductor 46 (cf. FIG. 7). In an alternative method the gold film, which serves as oxidation protection, is applied by thermal evaporation. The film then runs onto the roll magazine 14.6.

Metals which have a good electrical conductivity, do not diffuse into the semiconductors or form a diffusion barrier and do not enter into chemical reactions with these can generally be used as materials for producing the bonding.

In a subsequent operation the lift-off mask is detached from the carrier film 12 by a suitable solvent, such as acetone. The carrier film then carries a plurality of thermocouples (thermocouple chains), typically a few hundred. FIG. 7 shows details of three such thermocouple chains.

FIG. 7 shows the structure of the thermocouple chains, the legs from the first semiconductor 44 being arranged next to the legs from the second semiconductor 46 and connected to one another via the interconnection 52.

In a succeeding operation the carrier film 12 with the thin-film thermoelectric generator situated thereon is provided with a lacquer for protection against mechanical and chemical influences.

The lacquer film has openings which are arranged at points where gold-protected contact islands are provided for bonding of the thin-film thermo-generator. In an operation following the application of the lacquer film, the lacquer is tempered for approximately 2 hours at approximately 300° C. in a nitrogen atmosphere, which constitutes a protective gas atmosphere, so as to define the thermoelectric characteristics of the films to further advantage. This tempering produces a distinct increase in the electrical conductivity of the thin-film thermoelectric generator, without reducing its thermo-electric voltage, which leads to an increase in the efficiency.

The carrier film 12 extensively coated with thermocouples, is then divided, by means of a diamond abrasive wheel, for example, into segments of thin-film thermoelectric generators. The method may be as disclosed in DE 103 33 084 A1.

The segments are then joined by micro-assembly into stacks, connected in series and assembled to form thermo-electric components. Examples of corresponding methods are described in DE 103 33 084 A1.

Such thermo-electric components can be made up as miniaturized thermo-electric components and include, for example, thermoelectric generators as autonomous energy sources for micro-systems and sensor systems, infrared sensors, micro-calorimeters, and bio, chemical and high-frequency output sensors.

Alternatively, the carrier film is used in extensive format to produce plane structures, in order to convert heat radiation directly into electrical energy.

Although the invention has been described in terms of exemplary embodiments, it is not limited thereto. Rather, the appended claims should be construed broadly, to include other variants and embodiments, which may be made by those skilled in the art without departing from the scope and range of equivalents of the invention.

What is claimed is:

1. Method of manufacturing a thin-film thermo-electric generator, comprising the steps of:
coating of a carrier film with a first semiconductor of a first conductor type,
structuring of the first semiconductor,
coating of the carrier film with a second semiconductor of a second conductor type,
structuring of the second semiconductor, and
providing the carrier film for the coating and structuring steps as a film roll.

2. The method according to claim 1, further comprising running the carrier film from one roll holder onto a succeeding roll holder in each of the coating steps.

3. The method according to claim 1, further comprising running the carrier film from one roll holder onto a succeeding roll holder at least in the first semiconductor structuring step.

4. The method according to claim 3, wherein in the coating steps and in the structuring steps the carrier film in each case runs from one roll holder onto a succeeding roll holder, which serves to provide the carrier film for the succeeding step.

5. The method according to claim 1, wherein different pressures are set for each of the coating and structuring steps.

6. The method according to claim 5, wherein the method includes performing the coating steps under a vacuum and performing the structuring steps under atmospheric pressure.

7. The method according to claim 1, wherein the method includes performing the coating operations in a coating device, and introducing the carrier film into or extracting the carrier film from the coating device for coating.

8. The method according to claim 1, wherein the method includes performing at least one of the coating steps or structuring steps continuously.

9. The method according to claim 8, wherein the method includes setting different processing speeds for each of the coating and structuring operations.

10. The method according to claim 1, wherein the method includes cleaning the carrier film by inverse sputter etching prior to coating.

11. The method according to claim 10, wherein the inverse sputter etching is performed by argon ions in a vacuum.

12. The method according to claim 1, wherein the method includes running the carrier film onto a roll holder after the structuring of the second semiconductor and providing the carrier film on the roll holder for a subsequent bonding step.

13. The method according to claim 1, wherein the structuring is performed by photolithography and wet chemical means.

14. The method according to claim 1, further comprising tempering the carrier film prior to coating.

15. The method according to claim 14, wherein the tempering is performed at 250° C. to 350° C. for 1 to 3 hours.

16. The method according to claim 1, wherein the coating steps comprise a high-rate magnetron sputtering.

17. The method according to claim 16, wherein for each coating step the carrier film is coated at room temperature in a first part of the coating step and at an increased temperature in a second part of the coating step.

18. The method according to claim 17, wherein the carrier film is coated with a film thickness of 10 nm to 100 nm in the first part of the coating step, and the carrier film at a temperature of 200° C. to 300° C. is coated with a film thickness of 0.5 μm to 100 μm in the second part of the coating step.

19. The method according to claim 13, further comprising applying a lacquer coating after bonding.

20. The method according to claim 19, further comprising tempering the lacquer under a protective gas atmosphere after applying the lacquer coating.

21. The method according to claim 13, further comprising dividing the bonded carrier film into units of thin-film thermo-electric generators.

22. The method according to claim 21, further comprising a step of micro-assembly of the thin-film thermo-electric generator units into thermoelectric components.

23. The method according to claim 22, wherein the micro-assembly step includes stacking.

24. The method according to claim 1, comprising a further step of at least one of deformation, forming, bending, lacquering, cleaning, polishing, grinding, erosion, coating and assembly of the thermoelectric component.
